(19) United States
(12) Patent Application Publication
(10) Pub. No.: US 2010/0141969 A1
(43) Pub. Date: Jun. 10, 2010

(54) Method and Apparatus for Making Liquid Flexographic Printing Elements

(76) Inventors: David B. Brazier, High Wycombe (GB); Christian Barral, Uffholtz (FR)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 12/329,817

(22) Filed: Dec. 8, 2008

(51) Int. Cl. G06K 15/12; G03F 7/20

(52) U.S. Cl. 358/1.7; 430/306; 430/30

(57) ABSTRACT

A system and method for producing a flexographic relief image printing plate from a liquid photopolymer printing blank. The system comprises one or more apparatuses for performing steps to produce the relief image printing plate which are selected from the group consisting of a) a glass setting apparatus for setting a desired gauge of the relief image printing plate, b) an apparatus for controlling UV exposure of the printing plate during an exposure step, and/or c) an apparatus for automatically performing a masking exposure of the printing plate. A microcontroller is operatively connected to the one or more apparatuses and includes software for controlling the operation of the one or more apparatuses and data storage means for storing data relating to the at least one or more apparatuses. A user interface is operatively connected to the microcontroller and to the one or more apparatuses and comprises means for entering data into the data storage means and means for selecting information relating to the one or more apparatuses of the platemaking system.

### FIELD OF THE INVENTION

The present invention relates generally to improved method and apparatus for making liquid flexographic printing elements.

### BACKGROUND OF THE INVENTION

Flexographic printing is widely used in the production of newspapers and in the decorative printing of packaging media. Numerous photosensitive printing plate formulations have been developed to meet the demand for fast, inexpensive processing and long press runs.

Photosensitive printing elements generally comprise a support layer, one or more photosensitive layers, an optional slip film release layer, and an optional protective cover sheet. The protective cover sheet is formed from plastic or any other removable material that can protect the plate or photocurable element from damage until it is ready for use. The slip film may be disposed between the protective cover sheet and the photocurable layer(s) to protect the plate from contamination, increase ease of handling, and act as an ink-accepting layer. After exposure and development, the photopolymer flexographic printing plate consists of various image elements supported by a floor layer and anchored to a backing substrate. Flexographic printing elements can be manufactured in various ways including with sheet polymers and by the processing of liquid photopolymer resins.

Flexographic printing plates desirably work under a wide range of conditions. For example, they should be able to impart their relief image to a wide range of substrates, including cardboard, coated paper, newspaper, calendared paper, and polymeric films such as polypropylene, by way of example and not limitation. Importantly, the image should be transferred quickly and with fidelity, for as many prints as the printer desires to make.

Flexographic printing elements made from liquid photopolymer resin have the advantage that the uncured resin can be reclaimed from the non-image areas of the printing elements and used to make additional printing plates. Liquid photopolymer resins have a further advantage as compared to sheet polymer in terms of flexibility to enable the production of any required plate gauge simply by changing the machine settings. The plates are typically formed by placing a layer of liquid photopolymerizable resin on a glass plate but separated from the glass plate by the substrate and/or the coverfilm. Actinic light, such as UV light, is directed against the resin layer through a negative. The result is that the liquid resin is selectively cross-linked and cured to form a printing image surface that mirrors the image on the negative. Upon exposure to actinic radiation, the liquid photopolymer resin polymerizes and changes from a liquid state to a solid state to form the raised relief image. After the process is complete, non-crosslinked liquid resin can be recovered from the printing plates to make further plates.

Residual traces of liquid resin remaining in the regions of the resin which were protected from the actinic radiation by the opaque regions of the transparency are washed away using a developer solution. The cured regions are insoluble in the developer solution, and so after development a relief image formed of cured photopolymerizable resin is obtained. The cured resin is likewise insoluble in certain inks, and thus may be used in flexographic printing. The liquid photopolymerizable resin may also be exposed to actinic radiation from both sides of the resin layer.

Various processes have been developed for producing printing plates from liquid photopolymer resins as described, for example, in U.S. Pat. No. 5,213,949 to Kojima et al., U.S. Pat. No. 5,813,342 to Strong et al. and U.S. Patent Publication No. 2008/0107908 to Long et al., the subject matter of each of which is herein incorporated by reference in its entirety.

In the process described by Kojima et al., an image bearing transparency is disposed on a lower rigid plate that is transparent to actinic radiation (e.g., a glass plate), which in turn is covered with a thin transparent protecting film. A liquid photopolymerizable resin is then poured onto the protective film with the image bearing transparency between the glass plate and the protective film. A transparent substrate, such as a polyester or polyethylene terephthalate (PET) film is laminated on the poured resin by a roll laminating method, while simultaneously leveling the resin into a layer with a predetermined thickness by applying pressure to the resin by means of the roller used in the laminating method.

The upper light source box used to expose the resin layer for a short period of time to actinic radiation emitted from the upper light source to form a thin cured resin layer having a uniform thickness in the resin layer over the entire area facing the substrate. This thin cured resin layer thus formed by the back exposure is typically referred to as the “floor” layer. The resin layer is then exposed to actinic radiation which is emitted from the lower light source through the transmitting pattern (image pattern) of the image bearing transparency to form the relief portion or image.

After relief exposure, the uncured resin can be recovered. In a typical process, the uncured resin is physically removed from the plate in a further process step such that it can be reused to make further plates. Any residual traces of liquid resin remaining are then removed by nozzle washing or brush washing using a wash-out solution to obtain a washed-out plate, leaving behind the cured relief image. In liquid platemaking, resin recovery is an important factor relating to the production of photopolymerizable resin printing plates because the resins used to produce the plates are relatively expensive.

Thereafter, the cured printing plate may be subjected to various post exposure steps. For example, the plate may be completely immersed in water and exposed to actinic radiation such as UV light emitted from a light source to perform a complete curing of the entire plate and to increase plate strength.

Finally, the plate may be dried by blowing hot air on the plate or by using an infrared heater.

Plate gauge may be set by positioning a top exposure glass at a desired distance from a bottom exposure glass after dispensing liquid photopolymer on the protected bottom exposure glass. In addition, various techniques and mechanisms have been employed in the platemaking system to change the plate gauge. However, all of these prior art techniques employ some degree of manual set up and effort. For example, metal shims may be used to set the distance between two exposure glasses in combination with adjustments to the resin dispensing system and substrate lamination. In another alternative, built-in mechanical positioning devices that set the glass distance and other associated parts that are manually operated can be used. However, this can make changes to plate gauge cumbersome and prone to setting error.

Difficulties may be further compounded by the need to compensate for the shrinkage that occurs when the liquid resin is cured as well as the thickness of the film negative and protective film that do not form part of the finished plate gauge. This necessitates a calculation to be made in order to determine the distance the top glass and the bottom glass must be set apart to produce a particular plate gauge thickness. Thus, it would also be desirable to provide a method and a system for changing the gauge of printing plate in an efficient manner and that is capable of simplifying plate gauge setting.

The printing plate is thus exposed to actinic radiation to crosslink and cure the photopolymer printing plate. The exposure can typically be a blanket exposure, in which the entire surface is exposed to actinic radiation (i.e., to create the floor layer) or may be an imagewise exposure in which the photopolymer floor layer is exposed through a mask. A reclamation step can be beneficially be performed in which further savings can usefully be made by masking off selective areas of the plate by means of a physical mask or barrier positioned to block the UV radiation where there are no image elements. In all areas not exposed to U.V. radiation, the resin remains liquid after exposure and can then be reclaimed. This reclamation technique not only saves material costs of the photopolymer resin but also reduces the use and cost of developing chemistry and makes a lighter plate that is safer and easier to handle.

Various techniques have also been suggested in the art for masking off portions of the substrate to create the relief image in the photopolymer layer. For example, the mask may be placed directly on top of the backing substrate. However, in this approach, unevenness of the plate thickness can occur due to the mask displacing the liquid resin when the top and bottom glasses are positioned for platemaking. This can be compensated by temporarily increasing the distance between the upper and lower glass of the platemaking apparatus to provide space for the mask during mask exposure, but it is then necessary to reset the glass distance to control the plate gauge thickness in subsequent platemaking steps. With current platemaking systems, this can be time consuming, clumsy and prone to setting error.

Another technique places the mask inside a separate masking box located above the upper glass. However, this procedure is cumbersome and it can be difficult to locate the mask in a proper position so that it will align to printing image copy placed on the lower glass. The addition of the masking box also adds to the complexity and the cost of the platemaking system.

Thus, it would be desirable to provide an improved platemaking system that can more easily mask portions of the plate.

Furthermore, in order to create the image in the flexographic printing plate, photopolymer printing plates are generally exposed to UV radiation to create the desired image in the photopolymer by crosslinking and curing selected portions to create the image, which is typically accomplished using an array of UV fluorescent lamps. However, the UV output from the fluorescent lamps depends on the mercury vapor pressure within the lamp, which in turn depends on the coldest spot on the lamp. Generally, stable lamp operation is achieved when there is a difference of about 20° C. between the ambient air and the lamp tube. Thus, a free burning lamp will develop a tube temperature of about 40° C. at an air temperature of about 20° C.

In addition, when starting an array of lamps so that the lamps reach an optimum operating temperature, there may also be a slight difference between each of the lamps physically starting and the time for each lamp to reach optimum operating temperature for full UV output.

If the time needed for plate exposure is relatively long (i.e., 5 minutes or more), the difference in the start up of each individual lamp and the array reaching stable operating temperature is not so significant. However, when exposure times are short, such as the floor exposure with thinner gauge plates, the unevenness of lamp startup and stabilization becomes significant and may lead to difficulty in good exposure control and subsequently control of the floor thickness and uniformity. This becomes particularly significant for thinner gauge plates where very short back exposure times of only a few seconds may be needed.

Thus, it would also be desirable to provide a means for uniformizing the lamp output prior to exposing the printing plates.

The present invention relates to improved liquid platemaking to more efficiently and accurately produce a relief image printing element from a liquid photopolymer resin.

### SUMMARY OF THE INVENTION

It is an object of the present invention to provide improved methods of making flexographic printing plates from liquid photopolymers.

It is another object of the present invention to automate various steps of the plate making process to improve quality and consistency of the finished relief image printing plate.

It is another object of the present invention to simplify plate gauge setting.

It is still another object of the present invention to provide an improved method of compensating for resin shrinkage during curing.

It is yet another object of the present invention to provide an improved means for masking off portions of the photopolymerizable printing element.

It is still another object of the present invention to uniformize lamp output during UV floor exposure of the printing plate.

To that end, the present invention relates generally to a system for producing a flexographic relief image printing plate from a liquid photopolymer printing blank, said system comprising:

a) one or more apparatuses for performing steps to produce the relief image printing plate from the liquid photopolymer printing blank, wherein the one or more apparatuses are selected from the group consisting of a glass setting apparatus for setting a desired gauge of the relief image printing plate, an apparatus for controlling UV exposure of the printing plate during an imagewise exposure step, an apparatus for performing a masking exposure of the printing plate and combinations of one or more of the foregoing;

b) a microcontroller operatively connected to the one or more apparatuses of the platemaking system, said microcontroller comprising software for controlling the operation of the one or more apparatuses of the platemaking system and data storage means for storing data relating to the at least one or more apparatuses of the platemaking system; and

c) a user interface operatively connected to the microcontroller and to the one or more apparatuses of the platemaking system, said user interface comprising means for entering data into the data storage means and means for selecting information relating to the one or more apparatuses of the platemaking system.

In another embodiment, the present invention relates generally to a method of making a flexographic relief image printing plate in a liquid photopolymer platemaking process, the method comprising the steps of:

a) performing one or more process steps to produce a flexographic relief image printing plate in the liquid photopolymer platemaking process, wherein the one or more process steps are selected from the group consisting of (i) setting a plate gauge by setting a position of a top or a bottom glass, said top glass and said bottom glass defining a space into which a liquid photopolymer resin is contained (ii) controlling a UV exposure of the printing plate during an imagewise exposure step; (iii) performing an automatic masking exposure of the printing plate, and (iv) combinations of one or more of the foregoing;

b) instructing a microcontroller to perform steps relating to the one or more process steps, wherein said microcontroller controls the performance of the one or more process steps and stores data relating to the one or more process steps; and

c) interfacing with the microcontroller to enter data relating to the one or more process steps and/or to select information relating to the one or more process steps.

### BRIEF DESCRIPTION OF THE FIGURES

For a fuller understanding of the invention, reference is had to the following description taken in connection with the accompanying figures, in which:

FIG. 1 depicts an embodiment of a liquid platemaking system in accordance with one aspect of the present invention.

FIG. 2 depicts various view of a shutter array in accordance with one aspect of the present invention.

FIG. 3 depicts a screen layout for selecting a desired finished plate gauge in accordance with the present invention.

FIG. 4 depicts a subpage screen layout for entering calibration values for setting a plate gauge in accordance with the present invention.

Also, while not all elements may be labeled in each figure, all elements with the same reference number indicate similar or identical parts.

### DETAILED DESCRIPTION OF THE PREFERRED EMBODIMENTS

The present invention relates generally to improvements in liquid photopolymer platemaking methods and devices.

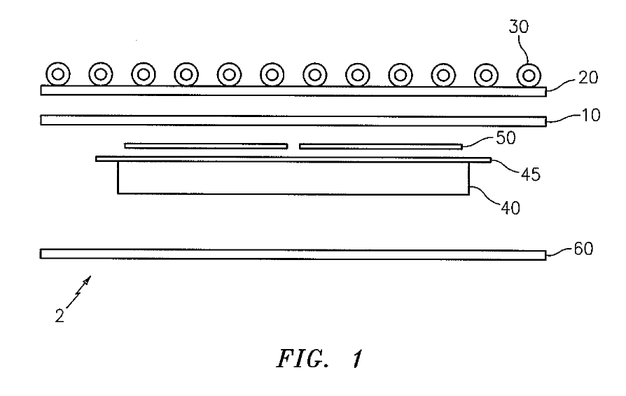

In one embodiment and as set forth in FIG. 1, the present invention relates generally to a platemaking system 2 for producing a flexographic relief image printing plate from a liquid photopolymer printing blank, said system comprising:

a) one or more apparatuses for performing steps to produce the relief image printing plate from the liquid photopolymer printing blank, wherein the one or more apparatuses are selected from the group consisting of a glass setting apparatus for setting a desired gauge of the relief image printing plate, an apparatus for controlling UV exposure of the printing plate during an imagewise exposure step, an apparatus for performing a masking exposure of the printing plate and combinations of one or more of the foregoing;

b) a microcontroller operatively connected to the one or more apparatuses of the platemaking system, said microcontroller comprising software for controlling the operation of the one or more apparatuses of the platemaking system and data storage means for storing data relating to the at least one or more apparatuses of the platemaking system; and

c) a user interface operatively connected to the microcontroller and to the one or more apparatuses of the platemaking system, said user interface comprising means for entering data into the data storage means and means for selecting information relating to the one or more apparatuses of the platemaking system.

The present invention also relates generally to a method of making a flexographic relief image printing plate in a liquid photopolymer platemaking process, the method comprising the steps of:

a) performing one or more process steps to produce a flexographic relief image printing plate in the liquid photopolymer platemaking process, wherein the one or more process steps are selected from the group consisting of (i) setting a plate gauge by setting a position of a top or a bottom glass, said top glass and said bottom glass defining a space into which a liquid photopolymer resin is dispensed; (ii) controlling a UV exposure of the printing plate during an imagewise exposure step; (iii) performing an automatic masking exposure of the printing plate, and (iv) combinations of one or more of the foregoing;

b) instructing a microcontroller to perform steps relating to the one or more process steps, wherein said microcontroller controls the performance of the one or more process steps and stores data relating to the one or more process steps; and

c) interfacing with the microcontroller to enter data relating to the one or more process steps and/or to select information relating to the one or more process steps.

In one embodiment, the one or more apparatuses is a glass setting apparatus in which a liquid photopolymer resin is contained in a space created between a top glass 10 and a bottom glass 60. The glass setting apparatus generally comprises:

a) a top exposure glass 10 that is restable on a plurality of guides (not shown);

b) a bottom glass 60 positionable at a desired distance from the top exposure glass 60 to create the desired gauge of the printing plate 40; and

c) means for moving the bottom glass 60 relative to the top glass 10 or visa versa,

whereby different gauge plates can be made by moving the bottom glass 60 relative to the top glass 10 or visa versa.

In addition, the platemaking apparatus may further comprise means (not shown) for dispensing liquid photopolymer resin (such as dispenser heads) spaced at a distance from the top exposure glass and settable relative to the plurality of guides (not shown) as well as means (not shown) for laminating a backing sheet (such as a lamination roller) onto the dispensed photopolymer resin, which is also settable relative to the plurality of guides.

In a preferred embodiment, the plurality of guides comprises at least two circular precision bars.

Furthermore, the glass setting apparatus comprises means (not shown) for detecting the location of the bottom glass 60, which is preferably a laser distance measuring device. After the locating of the bottom glass 60 has been detected, a powered precision height setting device or other similar device can be used to move the bottom glass and/or position the bottom glass 60 at the desired distance. In the alternative, the top glass can be moved in relation to the bottom glass.

The user interface typically comprises a touch screen and the microcontroller stores information relating to plate gauges normally used in production.

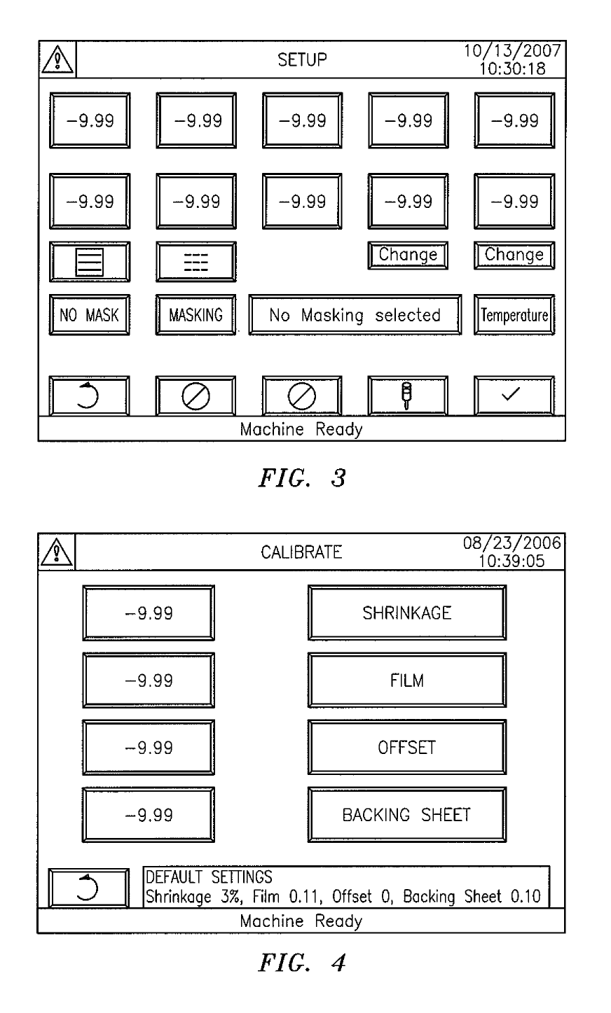

At the start of platemaking, the required finished plate gauge is selected by the operator via a touch screen that provides a selection of gauges normally used in production. These can easily be preset at the time of equipment installation or altered at will by the operator via a further page on the touch screen. A typical example of the SETUP screen showing the preset gauge selection is shown in FIG. 3. These finished plate gauges can either be preset or entered or altered by the operator on the touch screen.

The actual layout of the screen depicted in FIG. 3 may vary and the values shown (i.e., 9.99) are provided only for illustration. In practice, these values can be shown in mm and/or inch units.

To compensate for the photopolymer shrinkage and other factors that influence the finished plate gauge, the operator must also enter these values via a sub page on the touch screen as depicted in FIG. 4.

Again, the actual layout of the screen may vary and the values shown are for illustration purposes only. In practice, the film, offset and backing sheet values can be entered in mm and/or inch units. Shrinkage is typically entered as a percentage value.

It is noted that entry of these “calibration” values are only necessary at the time of initial installation or if the values of the entries change (for example if a different resin with a different shrinkage value is used).

Using the values entered on the calibration screen, the microcontroller (i.e., platemaker logic) then calculates the position of the bottom glass so that the finished plate gauge matches that selected on the initial SETUP screen. The fourth value shown (offset) to allow for small mechanical variations in the setting system, which is useful, for example, if the finished plates are consistently over or under gauge.

Thus, the microcontroller calculates the position of the bottom glass so that the finished plate gauge matches the selected value. When a particular plate gauge is selected, the powered system automatically moves the bottom glass to a position that will produce a finished plate gauge that corresponds to the gauge selected.

The actual position can be determined by the algorithm

G=P+F+(P−B)×S/100±OF,

Where:

G=glass distance

P=plate gauge

F=film thickness (negative+coverfilm)

B=backing sheet gauge

S=polymer shrinkage in % (i.e., for 3% shrinkage, a value of 3 is entered)

OF=offset factor

So, for example, if the operator enters a plate gauge of 6.35 mm on the setup page, then enters 3% shrinkage, 0.12 mm total film thickness, no offset and 0.1 mm backing sheet thickness on the “Calibrate” screen, the software algorithm will compute the glass distance as follows:

G=6.35+0.12+(6.35−0.1)×3/100±0=6.47+(6.25)×0.03=6.658 mm

In other words, in order to achieve a finished plate gauge of 6.35 mm, the top and bottom glasses would be automatically set 6.658 mm apart by the software setting algorithm to compensate for the values defined in the example above.

Thus, the system of the invention allows any normal plate gauge to be entered via a touch screen that automatically calculates and sets a compensated distance, while allowing for photopolymer resin shrinkage, film thickness and backing sheet thickness between the two glasses and the dispensing/lamination height in order to provide a finished plate gauge corresponding to the value entered.

The present invention greatly simplifies machine setup for different plate gauges. The present invention eliminates manual computation errors to allow for polymer shrinkage, backing sheet thickness and film thickness. In addition, the process of the invention eliminates the need for operator notes for setting machines and provides extremely rapid setup of plate gauge as compared to existing methods and eliminates manual efforts to change plate gauge. Also, the present invention eliminates plate gauge errors due to damaged shims. Finally, the process of the invention increases productivity and output yield due to automated, rapid machine settings and also reduces the risk of operator setting errors.

In another embodiment, the one or more apparatuses comprises an apparatus for performing a masking exposure of a liquid photopolymer printing element blank 40 that has been formed by dispensing resin into a spaced created between the top glass and the bottom glass and laminating a backing sheet 45 thereon, wherein the backing sheet 45 is laminated onto a surface of the liquid photopolymer resin 40 facing the bottom glass 10.

The masking apparatus generally comprises:

a) means (not shown) for detecting a position of the bottom glass 60;

b) means (not shown) for moving the bottom glass 60 to a desired position;

c) means for placing a mask 50 on top of the backing sheet 45, and

d) means for imagewise exposing the liquid photopolymer resin layer to actinic radiation through the mask 50 to create the relief image in the photopolymer resin layer.

The masking apparatus also comprises means for moving the bottom glass 60 to a desired position. The means for detecting the position of the bottom glass 60 is preferably a laser distance measuring device and the means for moving the bottom glass 60 to a desired position is preferably a powered precision height system as discussed above,

Furthermore, a mask exposure can also be performed on the printing plate by:
a) resetting the bottom glass to an increased distance;
b) placing a mask on top of the backing substrate;
c) positioning the top glass to a fixed position for performing a mask exposure;
d) once the mask exposure has been performed, moving the top glass away from the backing substrate and the mask to allow the mask to be removed;
e) resetting the bottom glass back to the optimum distance to produce the desired gauge of the printing element;
f) descending the top glass to the fixed position;
g) allowing the photopolymer resin to stabilize; and
h) exposing the relief image printing plate to actinic radiation to crosslink and cure image elements remaining on the printing plate after the mask exposure.

The position of the bottom glass 60 is detected using a precision measuring device such as a laser distance measuring device.

After the relief image printing element has been crosslinked and cured, the printing element may be removed from the platemaking device. Thereafter, additional process steps may be performed as is generally well known to those skilled in the art to prepare the relief image printing plates. These additional steps include developing the relief image printing plate, post-exposing the relief image printing plate and detacking the relief image printing plate, by way of example and not limitation.

At the start of the platemaking cycle, the bottom glass is automatically set to the optimum position needed for accurate resin dispensing and lamination of the backing substrate. Once this is done, the bottom glass is automatically reset by the powered system to an increased distance, which may typically be between about 1 and 10 mm, depending on various factors including the thickness of the mask. The operator then places the mask on top of the backing substrate, and the autocycle is resumed. The top glass descends to a fixed position and mask exposure takes place. Due to the increase setting distance, the top glass does not influence the liquid resin under the backing substrate.

On completion of the masking exposure, the top glass is moved upward, away from the backing substrate and the mask, allowing the mask to be removed. The autocycle is then resumed. The bottom glass is automatically reset by the powered system back to the optimum position needed for correct thickness control of the plate. The top glass then descends to its fixed datum position. In one preferred embodiment, there is a delay to allow the resin to stabilize followed by the main exposure to cure the image elements on the plate. Finally, the top glass lifts clear and the plate is removed from the platemaking system for further processing steps. These further processing steps include, for example, developing the relief image.

The present invention has the advantage of simplifying and improving existing masking methods. The present invention also eliminates manual operator settings for masking thus providing a highly repeatable and optimized masking process. In addition, the present invention eliminates plate gauge errors due to resin displacement caused by the mask and allows easy and accurate positioning of the mask, especially as compared to the masking box technique of the prior art.

The present invention increases productivity and output yield due to automated, rapid machine setting and reduces the risk of operator setting errors, because the operator is only placing and removing the mask. All of the other masking steps are performed automatically in the platemaking cycle.

In one embodiment, the present invention relates generally to a method and an apparatus that allows a mask to be placed inside the upper and lower glass of the platemaking system. The improved system of the invention completely eliminates the need for a masking box, improves alignment accuracy of the mask to the image elements while avoiding the thickness of the mask influencing the plate thickness tolerance and also overcomes the need for manual setting and resetting of the glass distance.

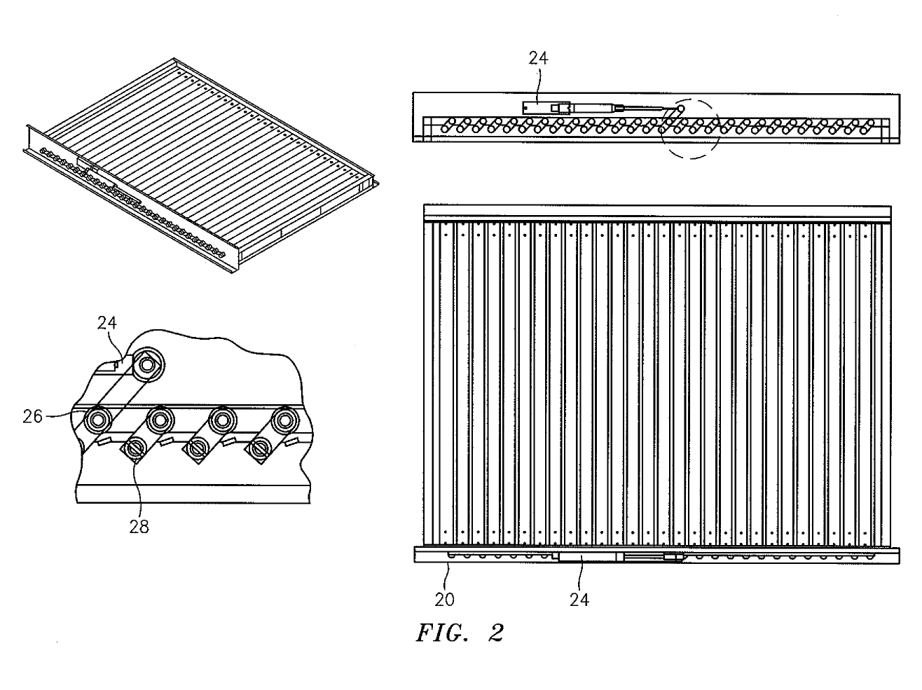

In another embodiment, the present invention relates to an improved means of controlling the UV exposure of photopolymer printing plates. More specifically, and as depicted in FIG. 2, the present invention relates to a shutter array 20 comprising a series of shutter blades 22 that are introduced between the lamp array and the plate to be exposed. In particular, the apparatus for controlling UV exposure of the printing plate during the floor exposure step typically comprises:
a) means for positioning the liquid photopolymer printing blank 40 proximate to a lamp array 30, wherein said lamp array 30 comprises a plurality of lamps that are capable of providing UV radiation for exposing the liquid photopolymer printing blank 40;
b) a shutter array 20 arranged between the lamp array 30 and the photopolymer printing blank 40, the shutter array 20 comprising a plurality of shutter blades 22 that are configured to operate together, whereby the plurality of shutter blades 22 substantially simultaneously open and close together; and
c) control means (not shown) for switching the lamps of the lamp array 30 on and off and for opening and closing the plurality of shutter blades 22 of the shutter array 20.

The control means directs the shutter blades 22 of the shutter array 20 to close prior to directing the plurality of lamps of the lamp array 30 to switch on and, once the lamps of the lamp array 30 have stabilized in temperature, simultaneously opens the shutter blades 22 of the shutter array 20 to allow the lamp array to perform the exposure of the printing blank 40. In a preferred embodiment, the plurality of lamps of the lamp array 30 comprise fluorescent switch-start lamps.

The series of shutter blades 22 are positioned between the lamp array 30 and the plate 40 to be exposed. As best seen in FIG. 2, these shutter blades 22 are capable of pivoting through approximately 90° by means of a first pivot point 26 and second pivot point 28 and operate together in such a way that they can either all be aligned at right angles to the lamp array 30, thereby allowing UV light from the lamp array 30 to expose the photopolymer printing plate 40 (open position) or be aligned approximately parallel to the lamp array 30 in such a way that they “nest” against each other, forming a continuous shield against passage of the UV light (closed position). A mechanism 24, such as a pneumatic cylinder, is operatively connected to the first pivot point 26 of one shutter blade 22 on at least one side of the shutter array 20. The mechanism 24 is connected to the control means (not shown), whereby the mechanism 24 causes the shutter blades 22 to open and close.

During operation, the shutter blades 22 are first closed and the lamps are then started and allowed to stabilize in temperature. This step can be accomplished while previous platemaking steps are being performed.

When exposure is required, the lamps of the lamp array 30 remain on and the shutter array 20 is opened, which can be achieved in less than about one second. At the end of the exposure time, the lamps of the lamp array 30 are switched off, which occurs at the same time for all of the lamps in the lamp array 30 and the shutter blades 22 are closed.

The use of the shutter blades 22 eliminates the effects of inconsistent lamp to lamp start up in the array 30 of UV lamps. In addition, the use of the shutter blades 22 eliminates the effects of varying UV output which results from lamp warm up. The use of the shutter blades 22 also allows optimum UV exposure even at extremely short exposure times which may typically be as short as about three seconds. Another desirable effect is the ability to use commonly available “switch start” lamps that do not rapidly start. Finally, the use of the shutter blades 22 also allows the start of exposure over the entire plate area at one time once the shutter blades 22 of the shutter array 20 are opened.

In addition, the present invention also relates generally to a method of controlling UV exposure of the liquid photopolymer printing blank using the shutter array described above during the imagewise exposure step, comprising the steps of:

a) positioning the liquid photopolymer printing blank proximate to a lamp array capable of imagewise exposing the liquid photopolymer printing blank, wherein said lamp array comprises a plurality of lamps that are capable of providing UV radiation for imagewise exposing the liquid photopolymer printing blank;

b) providing a shutter array comprising a plurality of shutter blades arranged between the lamp array and the photopolymer printing blank, said shutter blades being configured to operate together, whereby the plurality of shutter blades open and close together;

c) closing the shutter blades;

d) starting the plurality of lamps of the lamp array and allowing the lamps to stabilize in temperature;

e) opening the shutter array to perform the imagewise exposure of the printing blank; and

f) at the end of the desired imagewise exposure time, switching off the lamps of the lamp array and/or closing the shutters,

whereby effects of varying UV output as a result of inconsistent lamp warm up are at least substantially eliminated.

In one embodiment the desired imagewise exposure time is less than about 5 seconds, more preferably less than about 3 seconds.

In one preferred embodiment, the step of setting a plate gauge comprises the steps of:
a) setting a position of the bottom glass at an optimum distance to produce the desired gauge of the relief image printing plate;
b) performing a platemaking cycle, said platemaking cycle comprising the steps of introducing a liquid photopolymer resin between the top glass and the bottom glass and laminating a backing sheet on top of the dispensed resin; and
c) resetting the bottom glass to an increased distance.

Thus it can be seen that various improvements to a liquid platemaking process can be made that automize the liquid platemaking process while reducing the risk of operator errors.

It should also be understood that the following claims are intended to cover all of the generic and specific features of the invention described herein and all statements of the scope of the invention that as a matter of language might fall there between.

What is claimed is:

1. A platemaking system for producing a flexographic relief image printing plate from a liquid photopolymer printing blank, said system comprising:
a) one or more apparatuses for performing steps to produce the relief image printing plate from the liquid photopolymer printing blank, wherein the one or more apparatuses are selected from the group consisting of a glass setting apparatus for automatically setting a desired gauge of the relief image printing plate, an apparatus for controlling UV exposure of the printing plate during an exposure step, an apparatus for automatically performing a masking exposure of the printing plate and combinations of one or more of the foregoing;
b) a microcontroller operatively connected to the one or more apparatuses of the platemaking system, said microcontroller comprising software for controlling the operation of the one or more apparatuses of the platemaking system and data storage means for storing data relating to the at least one or more apparatuses of the platemaking system; and
c) a user interface operatively connected to the microcontroller and to the one or more apparatuses of the platemaking system, said user interface comprising means for entering data into the data storage means and means for selecting information relating to the one or more apparatuses of the platemaking system.

2. The system according to claim 1, wherein the one or more apparatuses comprise a glass setting apparatus, wherein a liquid photopolymer resin is contained in a space created between a top glass and a bottom glass, the glass setting apparatus comprising:
a) a top exposure glass, said top exposure glass restable on a plurality of guides;
b) a bottom glass positionable at a desired distance from the top exposure glass to create the desired gauge of the printing plate, and
c) means for moving at least one glass relative to the other glass and for positioning the bottom glass as the desired distance from the top glass,
whereby different gauge plates can be made by moving at least one glass relative to the other glass.

3. The system according to claim 2, wherein the plurality of guides comprise at least two circular precision bars.

4. The system according to claim 2, wherein the glass setting apparatus comprises means for detecting the location of the bottom glass, said means for detecting the location of the bottom glass comprising a laser distance measuring device.

5. The system according to claim 2, wherein the means for moving the bottom glass and/or positioning the bottom glass at the desired distance comprises a powered precision height setting device.

6. The system according to claim 2, wherein the user interface comprises a touch screen and the microcontroller stores information relating to plate gauges normally used in production.

7. The system according to claim 1, wherein the one or more apparatuses comprises an apparatus for performing a masking exposure of a liquid photopolymer printing element blank that has been formed by dispensing resin into a spaced created between a top glass and a bottom glass and laminating a backing sheet thereon, wherein the backing sheet is laminated onto a surface of the liquid photopolymer resin facing the bottom glass; the apparatus comprising:
a) means for detecting a position of the top glass;
b) means for moving the top glass to a desired position;
c) means for placing a mask on top of the backing sheet, and
d) means for exposing the liquid photopolymer resin layer to actinic radiation through the mask.

8. The system according to claim 7, comprising means for moving the bottom glass to a desired position.

9. The system according to claim 7, wherein the means for detecting the position of the top glass comprises a laser distance measuring device.

10. The system according to claim 7, wherein the means for moving the top glass to a desired position comprises a powered precision height system.

11. The system according to claim 1, wherein the one or more apparatuses comprises an apparatus for controlling UV exposure of the printing plate during the exposure step, the apparatus comprising:
a) means for positioning the liquid photopolymer printing blank proximate to a lamp array, wherein said lamp array comprises a plurality of lamps that are capable of providing UV radiation for exposing the liquid photopolymer printing blank;
b) a shutter array arranged between the lamp array and the photopolymer printing blank, the shutter array comprising a plurality of shutter blades that are configured to operate together, whereby the plurality of shutter blades substantially simultaneously open and close together; and
c) control means for switching the lamps of the lamp array on and off and for opening and closing the plurality of shutters of the shutter array;
whereby the control means directs the shutters of the shutter array to close prior to directing the plurality of lamps of the lamp array to switch on and, once the lamps of the lamp array have stabilized in temperature, simultaneously opens the shutters of the shutter array to allow the lamp array to perform the exposure of the printing blanks.

12. The system according to claim 11, wherein the plurality of lamps of the lamp array comprise fluorescent switch-start lamps.

13. A method of making a flexographic relief image printing plate in a liquid photopolymer platemaking process, the method comprising the steps of:
a) performing one or more process steps to produce a flexographic relief image printing plate in the liquid photopolymer platemaking process, wherein the one or more process steps are selected from the group consisting of (i) setting a plate gauge by setting a position of at least one of a top glass and a bottom glass, said top glass and said bottom glass defining a space into which a liquid photopolymer resin is dispensed; (ii) controlling a UV exposure of the printing plate during an exposure step; (iii) performing an automatic masking exposure of the printing plate, and (iv) combinations of one or more of the foregoing;
b) instructing a microcontroller to perform steps relating to the one or more process steps, wherein said microcontroller controls the performance of the one or more process steps and stores data relating to the one or more process steps; and
c) interfacing with the microcontroller to enter data relating to the one or more process steps and/or to select information relating to the one or more process steps.

14. The method according to claim 13, wherein the step of setting a plate gauge comprises the steps of:
a) selecting a desired finished plate gauge;
a) setting a position of the bottom glass at an optimum distance to produce the desired finished gauge of the relief image printing plate; and
b) performing a platemaking cycle, said platemaking cycle comprising the steps of introducing a liquid photopolymer resin between the top glass and the bottom glass and laminating a backing sheet on top of the dispensed resin,
wherein different gauge plates can be made by setting the position of the bottom glass relative to the position of the bottom glass.

15. The method according to claim 14, wherein the position of the bottom glass is detected using a laser distance measuring device.

16. The method according to claim 14, wherein finished plate gauges for various desired finished plate gauges are selected via a touch screen, said touch screen providing a selection of gauges usable in production.

17. The method according to claim 16, wherein the selection of gauges are pre-set or are entered or altered on the touch screen.

18. The method according to claim 16, further comprising the step of entering calibration values to compensate for photopolymer shrinkage.

19. The method according to claim 18, wherein the calibration values are entered on the touch screen.

20. The method according to claim 18, wherein the microcontroller calculates the position of the bottom glass so that the finished plate gauge matches the selected value and automatically moves the bottom glass to a position that will produce a desired finished plate gauge that corresponds to the gauge selected.

21. The method according to claim 13, wherein the step of performing an automatic masking exposure of the printing plate comprises the steps of:
a) detecting a position of the top glass;
b) resetting the top glass to an increased distance;
c) placing a mask on top of the backing substrate;
d) positioning the top glass to a fixed position for performing a mask exposure; and
e) once the mask exposure has been performed, moving the top glass away from the backing substrate and the mask to allow the mask to be removed.

22. The method according to claim 21, further comprising the steps of:
a) resetting the bottom glass back to an optimum distance for producing a desired gauge of the printing element;
b) descending the top glass to the fixed position;
c) allowing the photopolymer resin to stabilize; and
d) exposing the relief image printing plate to actinic radiation to crosslink and cure image elements remaining on the printing plate after the mask exposure.

23. The method according to claim 22, wherein additional process steps are performed to produce the cross-linked and cured relief image printing plate, the additional process steps comprising at least one of developing the relief image printing plate, post-exposing the relief image printing plate and detacking the relief image printing plate.

24. The method according to claim 13, wherein the step of controlling UV exposure of the liquid photopolymer printing blank during the exposure step comprises the steps of:
a) positioning the liquid photopolymer printing blank proximate to a lamp array capable of imagewise exposing the liquid photopolymer printing blank, wherein said lamp array comprises a plurality of lamps that are capable of providing UV radiation for exposing the liquid photopolymer printing blank;
b) providing a shutter array comprising a plurality of shutter blades arranged between the lamp array and the photopolymer printing blank, said shutter blades being configured to operate together, whereby the plurality of shutter blades open and close together;
c) closing the shutter blades;
d) starting the plurality of lamps of the lamp array and allowing the lamps to stabilize in temperature;
e) opening the shutter array to perform the exposure of the printing blank; and
f) at the end of the desired exposure time, switching off the lamps of the lamp array and/or closing the shutters,
whereby effects of varying UV output as a result of inconsistent lamp warm up are at least substantially eliminated.

25. The method according to claim 24, wherein the desired exposure time is less than about 5 seconds.

26. The method according to claim 25, wherein the desired exposure time is less than about 3 seconds.

27. The method according to claim 24, wherein the plurality of lamps of the lamp array comprises fluorescent switch-start lamps.

28. The method according to claim 24, wherein the exposure of the photopolymer plate is simultaneously performed over the entire plate area when the shutter array opens.
